(19) United States
(12) Patent Application Publication
(10) Pub. No.: US 2006/0071205 A1
(43) Pub. Date: Apr. 6, 2006

(54) Nanocrystal switch

(75) Inventor: Krzysztof Nauka, Redwood City, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: Hewlett-Packard Development Company, L.P.

(21) Appl. No.: 10/949,038

(22) Filed: Sep. 24, 2004

(51) Int. Cl. H01L 29/06

(52) U.S. Cl. 257/20

(57) ABSTRACT

A switch comprises a set of electrodes with a nanocrystal channel disposed between the electrodes. The nanocrystal channel has bridges between conductive nanocrystals. A gate electrode is disposed above the nanocrystal channel and is insulated there from. Voltage applied to the gate can modulate electrical conductivity of the bridges between the nanocrystals, thus modulating current flowing between the electrodes.

### BACKGROUND

Many processes for forming electronic circuitry rely on very expensive semiconductor fabrication processes and facilities. There is a desire to find less expensive methods of manufacturing electronic circuitry. Semiconductor fabrication processes may also use significant amounts of heat to produce the electronic circuitry. Some of the circuitry may be sensitive to excess heat. If circuitry is formed early in a process, heat produced by subsequent process steps may cause changes in earlier formed circuitry. It can be difficult to control and plan for the effects of such heat. The amount of heat prior to adverse damage is referred to as a thermal budget. Thermal budgets may vary, and may be difficult to control.

### BRIEF DESCRIPTION OF THE DRAWINGS

FIG. 1 shows a nanocrystal switch device structure in an example embodiment.

FIG. 2 shows an electrical conduction mechanism between adjacent nanocrystals connected with a material bridge in an example embodiment.

### DETAILED DESCRIPTION

In the following description, reference is made to the accompanying drawings that form a part hereof, and in which is shown by way of illustration specific embodiments that may be practiced. These embodiments are described in sufficient detail to enable those skilled in the art to practice the invention, and it is to be understood that other embodiments may be utilized and that structural, logical and electrical changes may be made without departing from the scope of the present invention. The following description is, therefore, not to be taken in a limited sense, and the scope of the present invention is defined by the appended claims.

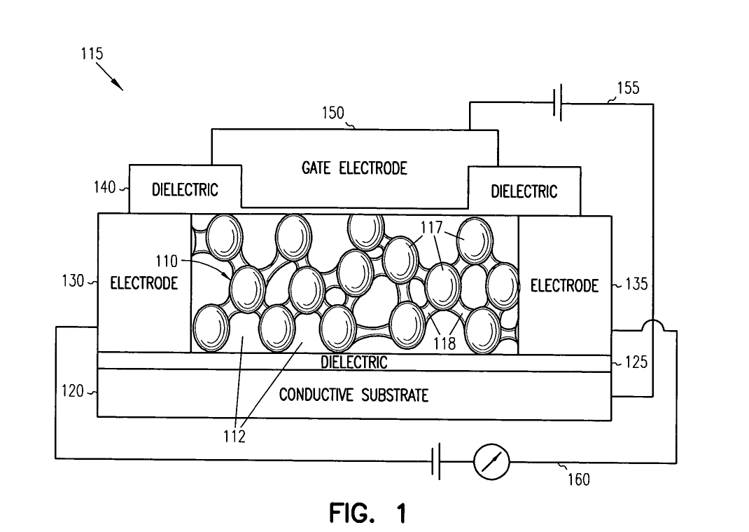

In FIG. 1, a channel 110 for a switch 115 is formed with a layer of nanocrystals. In one embodiment, metallic nanocrystals 117 are used for fabricating the channel. In further embodiments, semiconductor nanocrystals may be used to form the channel, especially if they exhibit conductivity in certain conditions.

Many commercially available metallic nanoparticles may be used as the nanocrystals, such as Cr, Fe, Ni, Co, Cu, Mo, Ga, In, Sn, Zn, Au, Pd, Ag, and Pt to name a few. In addition, semiconductor nanoparticles with low enough resistance, such as for example Si, GaSe, InSe, InP, CdSe, PbS, and PbSe may also be used. In further embodiments, semiconductor nanocrystals may be any conductive semiconductors in groups W, III-V, II-VI, and III-VI.

Employed nanoparticles may be coated with a protective layer of organic molecules. These organic molecules may prevent random close contact between the nanoparticles that may induce electrostatically induced attraction between the nanoparticles causing them to “stick” to each other and making their deposition difficult. The organic coating may be used to make handling of the nanoparticles easier.

In one embodiment, the channel 110 comprises multiple nanocrystals 117 that include material bridges 118 between them. The bridges may provide for electrical conductivity of the nanocrystals channel. The protective layer of organic molecules may provide the material used in formation of the material bridges 118 between the nanoparticles.

Formation of the material bridges 118 can be accomplished in a number of ways. In one embodiment, the nanoparticles are heat-treated causing particle sintering in the form of partial melting accompanied by reaction with the surface organic coating, and subsequent formation of the random network of material bridges between the adjacent nanoparticles. Similar effect can be obtained with alternative energy sources, like laser illumination, RF beam, plasma exposure, or particle bombardment.

In another embodiment bridges 118 can be formed by a catalytic process. The material bridges between adjacent nanoparticles are formed by chemical reaction(s) involving nanoparticles' surface and ambient surrounding nanoparticles. In a further embodiment selected parts of the nanoparticle' surface could catalyze reaction, causing formation of the material bridges.

In one embodiment voids 112 within the network of nanoparticles and bridges remain empty. In another embodiment they are filled with insulator such as, for example, highly resistive polymers (polyethylene, polyester, polyvineldifluorine, polystyrene, polycarbonate, polysiloxane, polypropylene, polyacrylate, polydimethylsiloxane, polymethylmethacrylate). This filling material can provide additional function of stabilizing and mechanically protecting and supporting potentially fragile network of nanoparticles 117 and bridges 118.

The size of the nanoparticles may be varied. In one embodiment, the nanoparticles have a diameter small enough to be consistent with a process for forming the channel. In one embodiment, the channel is printed, using a fluidjet printer, such as an inkjet printer. For example, the fluid jet printer ejects the nanoparticles onto a substrate 120 as described in more detail below.

In one embodiment when low processing temperatures are a concern, the temperature to form the material bridges can be decreased by using very small nanoparticles exhibiting suppression of the melting point. This way, sintering processing to form the bridges may be accomplished at very low temperatures. Very small nanoparticles exhibit melting point suppression, meaning that they melt at temperatures below the bulk melting point. For example, 2 nm particles of Au melt at around 300° C.

Switch 115 in one embodiment comprises the substrate 120, such as a silicon wafer in one embodiment. Other substrates may also be used. A dielectric layer 125 is then formed on the substrate by one of many different known techniques. Electrodes 130 and 135 are supported by the dielectric layer 125, with the channel 110 formed between them. A further dielectric layer 140 (gate dielectric) is formed over the corresponding electrodes 130 and 135, and the channel 110. Then, gate electrode 150, aligned with respect to the electrodes 130, 135, and channel 110 is formed on the top of gate dielectric 140. The electrodes 130, 135 may be formed of conductive material, such as metal or highly doped semiconductor materials.

Voltage applied horizontally, between electrodes 135 and 130, causes electric current flow across the channel 110.

When voltage is applied to the gate electrode 150, by circuitry 155 coupling the gate electrode 150 and the substrate 120, a vertical electric field modifies properties of defects present within the bridges 118 between the nanocrystals 117 of the channel 110. Thus, a horizontal current is modulated along the network of nanocrystals 117 in the channel 110, as observed by circuitry 160 coupling the electrode 130 and the electrode 135.

In one embodiment, the channel 110 exhibits valve, or switch-like properties. A sharp transition between substantially conductive versus non-conductive behavior occurs over a fairly narrow change in electric field or voltage applied to the electrode 150. The switch 115 is configured much like a field effect transistor, with electrodes 130 and 135 serving as source and drain, and electrode 150 serving as the gate.

In one embodiment, the bridges can be crafted by proper selection of temperature and organic molecules used in formation of the bridges 118 as above, to provide an I-V relationship different from one obtainable for classic Si transistors. It may operate in different voltage regimes and high or low current ranges for a given voltage. A multi-state device may also be produced. The channel conductivity may be continuously or quasi-continuously varied as gate voltage is increased. Realization of regions of negative resistance may also be obtained. Further, the switch may be integrated with nanocrystal-based optoelectronic devices fabricated adjacent to the switch.

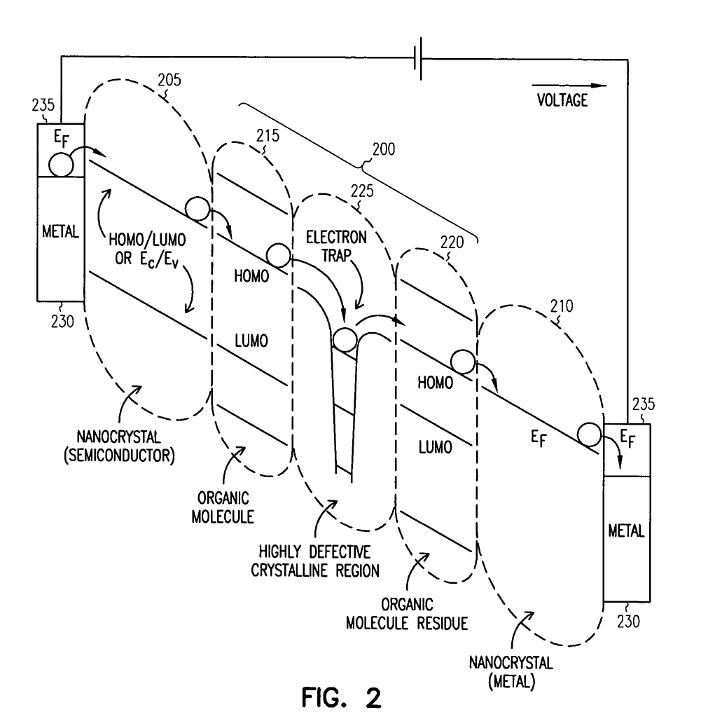

FIG. 2 illustrates electrical conduction mechanism within a material bridge 200 formed between adjacent nanocrystals 205 and 210. For illustration nanocrystal 205 represents a semiconductor nanocrystal, while nanocrystal 210 represents a metallic nanoparticle. In various embodiments, both nanocrystals are either semiconductor or metal. Three potential components of the material bridge are shown: complete organic molecule 215, organic molecule residue 220 and defective, inorganic crystalline region 225. Any combination of these three components can constitute the material bridge 200.

The material bridge 200 is formed in at least two different ways. In one embodiment, the material bridges are formed from organic molecules 215 or molecule residue 220. In one embodiment, nanocrystals 205 and 210 are coupled directly with molecules 215. Nanocrystals are packed into two dimensional or three dimensional arrays, with the organic molecules 215, 220 providing a bridge 200 between adjacent nanocrystals 205, 210. They can also form less organized structure with organic molecules 215, 220 providing a network of randomly connected nanoparticles. Amines are common organic molecules that are used, and others may also be used.

A further type of material bridge 200 is formed at the onset of melting of the nanocrystals, which typically have a fairly low melting point. At the melting point, formation of highly defective nanocrystal crystalline regions 225 of the same material as the nanocrystals 205 and 210 occurs. With organic molecules 215 and 220 present in the original nanocrystals, annealing of a packed array forms highly defective bridges containing both nanocrystal material 225 and remains of the organic molecules 215 and 220.

Nanocrystals 205, 210 formed with such bridges 200 may be coupled to electrodes as indicated at 230 and 235, which may further be coupled to circuitry 240 to provide a voltage gradient to observe conductivity. A voltage gradient of 1 to 2 volts may be sufficient.

Transport across the material bridges appears to be the sum of transport processes mediated by defects and allowed states within the bridges. They appear to provide hopping conductivity as observed in both metallic and semiconductor nanocrystals arrays. Hopping transport is described as a combination of conduction via mixture of discrete allowed states (as in 215, 220) and a large number of trap-release processes (as in 225), where each trapping center has finite energy, capture cross-section and release probability that are determined by its origin.

Most of the individual transport processes illustrated in FIG. 2 are a function of electric field. For example, most of the traps can exhibit Frankel-Poole effect, where application of an electric field changes trap parameters by orders of magnitude. Similarly, transport through allowed discrete states can be modified by the electric field.

The switch 115 may be manufactured in many different ways. In one embodiment blank layer of nanoparticles is deposited by spraying or spinning, followed by photolithographic patterning and removal of undesired parts of the original nanoparticle layer. Alternatively, desired pattern of nanoparticles can be obtained by deposited through a shadow mask. In another embodiment, the switch is manufactured using jetted particles to print the desired, nanoparticle coated regions. Ink jet printer can be used to deposit the nanoparticles. This can provide a very low temperature deposition of the channel. An ink jet printing process may be used that utilizes particles suspended in a liquid medium, such as a solvent that evaporates after printing, leaving the particles behind in the shape printed.

In one embodiment dielectric material filling voids 112 can be deposited in conjunction with nanoparticles. Further heat treatment may be required to polymerize the oligomers filling the voids.

To form the switch 115, electrodes 130 and 135 are first printed on the dielectric layer 125 of substrate 120. The electrodes may be formed of many different conductive materials, such as metals or highly conductive semiconductors. The nanoparticles of the channel 110 are then printed, with organic material also included in the liquid medium. Dielectric layer 140 is then printed, and may be formed of SiO₂ or other type of insulative material, such as those commonly used in integrated circuit processing methods. Finally, the gate electrode 150 is printed. The gate electrode may also be formed of a conductive metal or other conductive material. In one embodiment, dielectric layer 125 is also printed prior to printing of electrodes 130 and 135.

After or during printing of the nanoparticles of the channel 130, material bridges 118, 200 are formed by the aforementioned processes. In further embodiments, switch 115 may be formed in a hybrid fashion. For example, metal and dielectric layers may be formed using classical integrated circuit processes such as oxide growth, patterning, etc. The remainder of the switch 115 may be printed. Many other combinations of the use of printing and integrated circuit processing may be utilized.

The Abstract is provided to comply with 37 C.F.R. §1.72(b) to allow the reader to quickly ascertain the nature and gist of the technical disclosure. The Abstract is submitted with the understanding that it will not be used to interpret or limit the scope or meaning of the claims.

1. A switch comprising:
a set of electrodes;
a nanocrystal channel disposed between the electrodes, wherein the nanocrystal channel includes bridges between conductive nanocrystals; and
a gate electrode disposed above the nanocrystal channel and insulated therefrom.

2. The switch of claim 1 wherein the nanocrystal channel is conductive when subjected to an electric field.

3. The switch of claim 2 wherein the gate electrode provides the electric field.

4. The switch of claim 1 wherein electrical conduction via the bridges between the nanocrystals can be modulated by an electric field.

5. The switch of claim 1 wherein the bridges comprise organic material.

6. The switch of claim 1 wherein the bridges include defective regions made of the same material as nanoparticles.

7 The switch of claim 1 wherein the bridges comprise organic material and/or defective regions made of a same material as the nanoparticles.

8. The switch of claim 1 wherein the nanocrystals are metal.

9. The switch of claim 7 wherein the nanocrystals are selected from a group consisting of Cr, Fe, Ni, Co, Cu, Mo, Ga, In, Sn, Zn, Au, Pd, Ag, and Pt.

10. The switch of claim 1 wherein the nanocrystals are semiconductor nanocrystals.

11. The switch of claim 10 wherein the nanocrystals are selected from a group consisting of Si, GaSe, InSe, InP, CdSe, PbS, and PbSe.

12. The switch of claim 1 wherein voids within the network of nanocrystals and bridges are filled with dielectric.

13. The switch of claim 12 wherein highly resistive polymer is used as dielectric.

14. The switch of claim 13 where highly resistive polymer is selected from the group consisting of: polyethylene, polyester, polyvineldifluorine, polystyrene, polycarbonate, polysiloxane, polypropylene, polyacrylate, polydimethylsiloxane, polymethylmethacrylate.

15. A channel comprising:
a plurality of conductive nanocrystals; and
a plurality of bridges disposed between adjacent conductive nanocrystals, the bridges comprising highly defective nanocrystal regions between organic molecule residue and/or organic molecules.

16. The channel of claim 11 wherein the conductive nanocrystals are semiconductor nanocrystals formed from conductive semiconductors in groups IV, III-V, II-VI, or III-VI.

17. A method comprising:
forming conductive strips;
forming a nanocrystal channel between the conductive strips;
forming a layer of dielectric over the conductive strips and the channel; and
forming a gate electrode over at least a portion of the nanocrystal channel.

18. The method of claim 17 wherein the electrodes comprise conductive material.

19. The method of claim 17 wherein the electrodes comprise metal or highly-doped semiconductor.

20. The method of claim 17 wherein the nanocrystal channel is formed with bridges between adjacent conductive nanocrystals.

21. The method of claim 20wherein the nanocrystals are selected from a group consisting of Cr, Fe, Ni, Co, Cu, Mo, Ga, In, Sn, Zn, Au, Pd, Ag, and Pt.

22. The method of claim 20 wherein the nanocrystals are selected from a group consisting of Si, GaSe, InSe, inP, CdSe, PbS, and PbSe.

23. The method of claim 20 wherein the nanocrystals are selected from a group consisting of conductive semiconductors in groups IV, III-V, II-VI, or III-VI.

24. A method comprising:
forming conductive strips;
printing a nanocrystal channel between the conductive strips;
forming a layer of dielectric over the conductive strips and channel; and
forming a gate electrode over at least a portion of the nanocrystal channel.

25. The method of claim 24 wherein printing comprises using an inkjet printer with a solvent having nanoparticles of materials corresponding to elements that are printed.

26. The method of claim 25 wherein the conductive strips comprise metal nanoparticles.

27. The method of claim 24 wherein the conductive strips are formed using integrated circuit processing steps.

28. The method of claim 24 wherein the conductive strips are formed by printing.

29. The method of claim 24 wherein at least one of the conductive strips, layer of dielectric and gate electrode are formed by printing.

30. The method of claim 24 wherein the dielectric comprises SiO₂.
